(19) United States
(12) Patent Application Publication
(10) Pub. No.: US 2025/0015052 A1
(43) Pub. Date: Jan. 9, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventors: JUNBYEONG LEE, Suwon-si (KR); JINMO KWON, Suwon-si (KR)

(21) Appl. No.: 18/631,231

(22) Filed: Apr. 10, 2024

(30) Foreign Application Priority Data
Jul. 5, 2023 (KR) 10-2023-0086933

(51) Int. Cl. H01L 25/065; H01L 23/00; H01L 23/31; H01L 25/00

(52) U.S. Cl. CPC H01L 25/0657; H01L 23/3128; H01L 24/29; H01L 24/32; H01L 24/48; H01L 24/73; H01L 25/50; H01L 2224/29005; H01L 2224/32145; H01L 2224/32225; H01L 2224/48145; H01L 2224/48225; H01L 2224/73265; H01L 2225/06506; H01L 2225/0651; H01L 2225/06562; H01L 2924/1815

(57) ABSTRACT

A semiconductor package includes a package substrate, a first group of semiconductor chips disposed on the package substrate and including at least two lower semiconductor chips that are sequentially stacked and are offset in a first horizontal direction, a second group of semiconductor chips stacked on the first group of semiconductor chips and including at least two upper semiconductor chips that are sequentially stacked and are offset in a direction opposite to the first horizontal direction, first bonding wires electrically connecting the chip pads of the first group of semiconductor chips to first substrate pads of the package substrate, second bonding wires electrically connecting the chip pads of the second group of semiconductor chips to second substrate pads of the package substrate and a molding member covering the first group of semiconductor chips and the second group of semiconductor chips on the package substrate.

### CROSS-RELATED TO RELATED APPLICATION

This application claims priority under 35 U.S.C. § 119 to Korean Patent Application No. 10-2023-0086933, filed on Jul. 5, 2023, in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a semiconductor package including a plurality of chips sequentially stacked on a package substrate and a method of manufacturing the same.

### DISCUSSION OF RELATED ART

In a multi-chip package (MCP), a plurality of semiconductor chips may be sequentially attached on a package substrate in a cascade structure using an adhesive film such as a die attach film (DAF) through a die attach process. In case of the structure having chips stacked in layers, An impedance mismatch between chips may be reduced in MCPs having chips stacked in layers by using chip to chip bonding to electrically connect the stacked semiconductor chips and the package substrate. In this case, an occupied volume ratio of a molding member on a first-stage chip may be high, so in a high-temperature and high-humidity environment, an interfacial peeling failure may occur due to a difference in hygro-mechanical stress, or hygro-swelling expansion, between the molding layer and the chip at a corner of an overhang portion of the first-stage chip that is exposed to the molding layer.

### SUMMARY

Example embodiments provide a semiconductor package capable of reducing or preventing interfacial peeling. Example embodiments provide a semiconductor package having improved reliability.

Example embodiments provide a method of manufacturing the semiconductor package.

According to example embodiments, a semiconductor package includes a package substrate having an upper surface and a lower surface opposite to each other, the package substrate including a first side portion and a second side portion extending in a direction parallel to a first direction and facing each other; a first group of semiconductor chips disposed on the upper surface of the package substrate, the first group of semiconductor chips including a first lower semiconductor chip and a second lower semiconductor chip stacked on the first lower semiconductor chip and respectively comprise first surfaces facing upwards on which chip pads are formed, and the first group of semiconductor chips are sequentially offset in a second direction perpendicular to the first direction; a second group of semiconductor chips disposed on the first group of semiconductor chips, the second group of semiconductor chips including a first upper semiconductor chip and a second upper semiconductor chip stacked on the first upper semiconductor chip and respectively comprise a first surfaces facing upwards on which upper chip pads are formed, and the second group of semiconductor chips are sequentially offset in the direction opposite to the second direction; a plurality of first bonding wires electrically connecting the chip pads to a plurality of first substrate pads of the package substrate; a plurality of second bonding wires electrically connecting the upper chip pads to a plurality of second substrate pads of the package substrate; and a molding member covering the first group of semiconductor chips and the second group of semiconductor chips on the upper surface of the package substrate. The second upper semiconductor chip overlaps an overhang region of the first lower semiconductor chip that protrudes from a side of the second lower semiconductor chip.

According to example embodiments, a semiconductor package includes a package substrate; a first group of semiconductor chips disposed on the package substrate, the first group of semiconductor chips including at least two lower semiconductor chips that are stacked offset in a first horizontal direction such that a first surface of each of the at least two lower semiconductor chips on which chip pads are formed face upward; a second group of semiconductor chips disposed on the first group of semiconductor chips, the second group of semiconductor chips including at least two upper semiconductor chips that are stacked offset in a direction opposite to the first horizontal direction such that a first side of each of the at least two upper semiconductor chips on which upper chip pads are formed face upward; a plurality of first bonding wires electrically connecting the chip pads to a plurality of first substrate pads of the package substrate; a plurality of second bonding wires electrically connecting the upper chip pads to a plurality of second substrate pads of the package substrate; and a molding member covering the first group of semiconductor chips and the second group of semiconductor chips on the package substrate. Each of the first group of semiconductor chips and the second group of semiconductor chips has a first side surface and a second side surface opposite to the first side surface. The first side surfaces of the first group of semiconductor chips are arranged in one-to-one correspondence with the first side surfaces of the second group of semiconductor chips.

According to example embodiments, a semiconductor package includes a package substrate; a first group of semiconductor chips disposed on the package substrate, the first group of semiconductor chips including at least two lower semiconductor chips that are stacked offset in a first horizontal direction such that a first surface of each of the at least two lower semiconductor chips on which chip pads are formed face upward; a second group of semiconductor chips disposed on the first group of semiconductor chips, the second group of semiconductor chips including at least two upper semiconductor chips that are stacked offset in a direction opposite to the first horizontal direction such that a first surface on which upper chip pads are formed face upward; a plurality of first bonding wires electrically connecting the chip pads to a plurality of first substrate pads of the package substrate; a plurality of second bonding wires electrically connecting the upper chip pads to a plurality of second substrate pads of the package substrate; and a molding member covering the first group of semiconductor chips and the second group of semiconductor chips on the package substrate. Each of the first group of semiconductor chips and the second group of semiconductor chips has a first side surface adjacent to the first side portion of the package substrate and a second side surface opposite to the first side portion. The first group of semiconductor chips are arranged in one-to-one correspondence with the second group of semiconductor chips. Each of the at least two lower semiconductor chips of the first group of semiconductor chips overlap with corresponding ones of the at least two upper semiconductor chips of the second group of semiconductor chips. The first side surface of a lowermost lower semiconductor chip among the first group of semiconductor chips and the first side surface of an uppermost upper semiconductor chip among the second group of semiconductor chips are located on a first plane. The first side surface of middle ones of the first group of semiconductor chips and the second group of semiconductor chips disposed adjacent to each other are located on a second plane different than the first plane.

According to example embodiments, a semiconductor package may include a first group of semiconductor chips disposed on a package substrate, a second group of semiconductor chips stacked on the first group of semiconductor chips, and a molding member. First and second lower semiconductor chips of the first group of semiconductor chips may be sequentially offset in a first horizontal direction, and first and second upper semiconductor chips of the second group of semiconductor chips may be sequentially offset in a direction opposite to the first horizontal direction. The first lower semiconductor chip may be aligned with the second upper semiconductor chip, and the second lower semiconductor chip may be aligned with the first upper semiconductor chip.

A volume occupied by a molding region above an overhang region of the first lower semiconductor chip may be reduced by a volume of an overhang region of the second upper semiconductor chip. Accordingly, it may be possible to reduce or prevent an interfacial peeling defect due to a difference in hygro-swelling expansion displacements at an edge portion of the overhang region of the first lower semiconductor chip below the molding region.

Further, chip pads of the first and second semiconductor chips stacked in a cascade manner may be electrically connected to the package substrate by upper and lower wires using a chip-to-chip wire bonding method. Accordingly, it may be possible to reduce impedance mismatch between chips and provide improved electrical characteristics suitable for a high-speed memory package.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating a semiconductor package in accordance with example embodiments.

FIG. 2 is a plan view of FIG. 1.

FIGS. 3 to 15 are views illustrating a method of manufacturing a semiconductor package in accordance with example embodiments.

FIG. 16 is a cross-sectional view illustrating a semiconductor package in accordance with example embodiments.

FIG. 17 is a cross-sectional view illustrating a semiconductor package in accordance with example embodiments.

### DETAILED DESCRIPTION

Hereinafter, example embodiments will be explained in detail with reference to the accompanying drawings. In all figures in this specification, directions indicated by an arrow and a reverse direction thereto may be considered as the same direction.

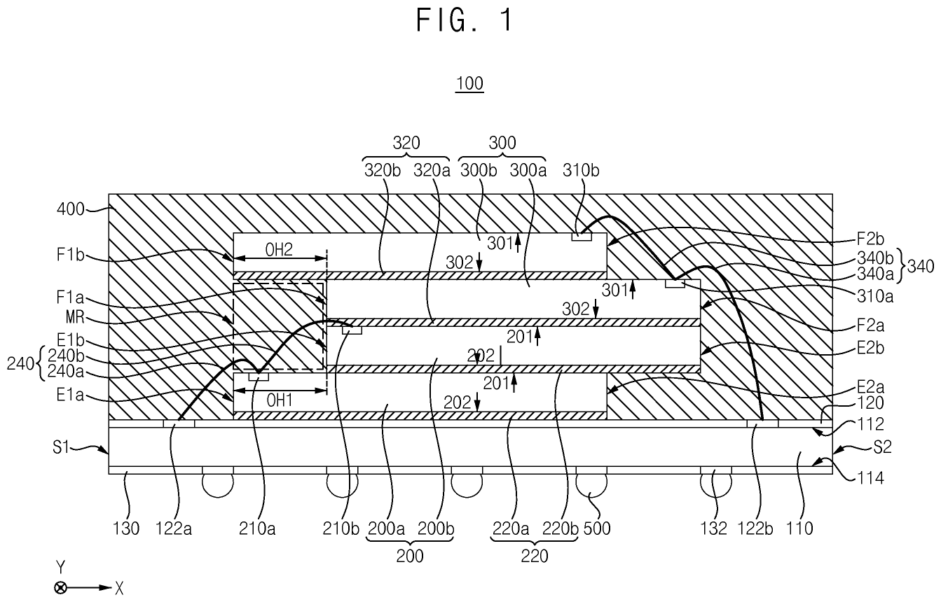

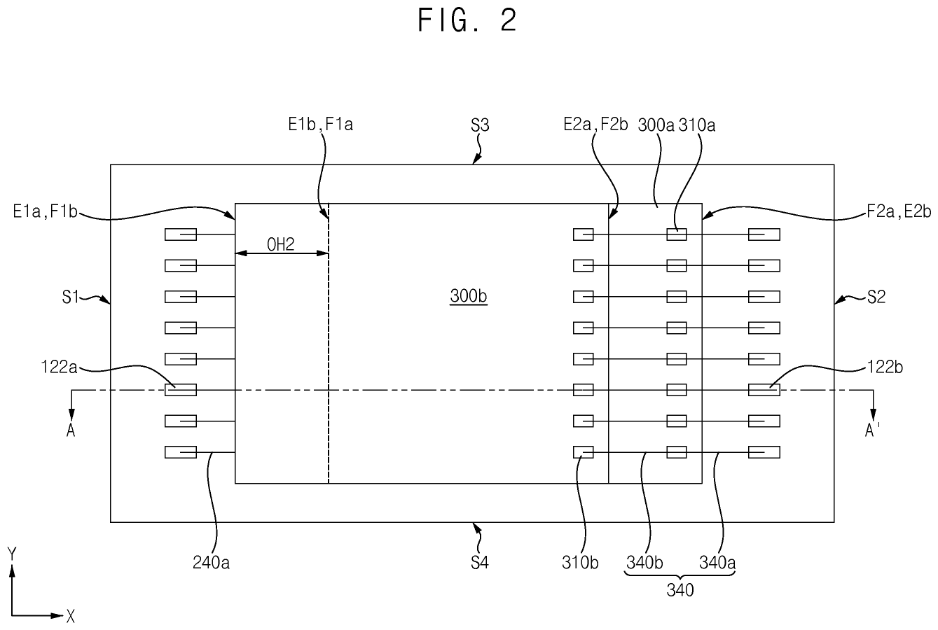

FIG. 1 is a cross-sectional view illustrating a semiconductor package in accordance with example embodiments. FIG. 2 is a plan view of FIG. 1. FIG. 2 is a plan view illustrating the semiconductor package in FIG. 1, wherein a molding member is omitted.

Referring to FIG. 1 and FIG. 2, a semiconductor package 100 may include a package substrate 110, a first group of semiconductor chips 200, a second group of semiconductor chips 300, and a molding member 400. The first group of semiconductor chips 200 may be disposed on the package substrate 110. The second group of semiconductor chips 300 may be stacked on the first group of semiconductor chips 200. The semiconductor package 100 may further include conductive connection members. The conductive connection members may include first bonding wires 240 and second bonding wires 340. The first bonding wires 240 may electrically connect the first group of semiconductor chips 200 to the package substrate 110. The second bonding wires 340 may electrically connect the second group of semiconductor chips 300 to the package substrate 110. Additionally, the semiconductor package 100 may further include external connection members 500. The first group of semiconductor chips 200 may include at least two lower semiconductor chips sequentially stacked on each other, and the second group of semiconductor chips 300 may include at least two upper semiconductor chips sequentially stacked on each other.

The first group of semiconductor chips 200 may include a first lower semiconductor chip 200a and a second lower semiconductor chip 200b. The second lower semiconductor chip 200b may be stacked on the first lower semiconductor chip 200a. The second group of semiconductor chips 300 may include a first upper semiconductor chip 300a and a second upper semiconductor chip 300b. The first upper semiconductor chip 300a may be stacked on the second lower semiconductor chip 200b. The second upper semiconductor chip 300b may be stacked on the first upper semiconductor chip 300a.

Additionally, the semiconductor package 100 may be a multi-chip package (MCP) including semiconductor chips of the same or different types. The semiconductor package 100 may be a System In Package (SIP) including a plurality of semiconductor chips stacked or variously arranged in a single package. The plurality of semiconductor chips may be being capable of performing one or more functions associated with an electronic system.

The first group of semiconductor chips 200 and the second group of semiconductor chips 300 may include a logic chip including a logic circuit or a memory chip including a memory circuit. The logic chip may be a controller that controls a memory chip. The logic chip may be a processor ship such as an application-specific integrated circuit (ASIC), an application processor (AP), etc. serving as a host such as central processing unit (CPU), a graphics processing unit GPU, or system on chip (SOC). The memory chip may include, for example, volatile memory devices such as static random-access memory (SRAM) devices, dynamic random-access memory (DRAM) devices, etc. and non-volatile memory devices such as flash memory devices, parallel random access memory (PRAM) devices, magnetoresistive random-access memory (MRAM) devices, resistive random-access memory (RRAM) devices, etc.

In example embodiments, the package substrate 110 may be a substrate having an upper surface 112 and a lower surface 114 opposite to each other. The first lower semiconductor chip 200a may be disposed on the upper surface 112 of the package substrate 110. The external connection member 500 may be disposed on the lower surface 114 of the package substrate 110.

The package substrate 110 may include a printed circuit board (PCB), a flexible substrate, or a tape substrate, but the present inventive concept is not limited thereto and the package substrate 110 may be embodied as any of various substrates. The printed circuit board may be a multilayer circuit board having vias and various circuits therein. The package substrate 110 may include internal wirings for electrical connection with the first group of semiconductor chips 200 and for electrical connection with the second group of semiconductor chips 300. The package substrate 110 may include internal wirings for electrical connection between the first group of semiconductor chips 200 and the second group of semiconductor chips 300.

The package substrate 110 may include a first side portion S1 and a second side portion S2 extending in a direction perpendicular to the upper surface 112 and parallel to a second direction (Y direction) and facing each other. The package substrate 110 may include a third side portion S3 and a fourth side portion S4 extending in a direction parallel to a first direction (X direction) perpendicular to the second direction and facing each other.

The package substrate 110 may include a plurality of substrate pads arranged along one or more sides (e.g., the first side portion S1, the second side portion S2, the third side portion S3, the fourth side portion S4) of the package substrate 110. The substrate pads may include first substrate pads 122a spaced apart from each other along the first side portion S1 of the package substrate 110 and second substrate pads 122b spaced apart from each other along the second side portion S2 of the package substrate 110. The first substrate pads 122a and the second substrate pads 122b may be respectively connected to the wirings. The wirings may extend on the upper surface 112 of the package substrate 110 or within the package substrate 110. For example, at least a portion of the wiring may be used as a landing pad or as the substrate pad on the substrate.

Although only some substrate pads are illustrated in the figures, it will be understood that the number, shape, and arrangement of the substrate pads are provided as examples, and the present inventive concept is not limited thereto. Since the wirings and the substrate pads are well known in the art to which the present inventive concept pertains, illustration and description concerning these elements may be omitted.

A first insulating layer 120 may be formed on the upper surface 112 of the package substrate 110. The first insulating layer 120 may expose the first substrate pads 122a and the second substrate pads 122b. The first insulating layer 120 may cover the upper surface 112 of the package substrate 110 and may expose the first substrate pads 122a and the second substrate pads 122b. For example, the first insulating layer may include a solder resist.

In example embodiments, the first group of semiconductor chips 200 may be disposed on the package substrate 110. The first group of semiconductor chips 200 may be fixed using lower adhesive films 220. A first lower semiconductor chip 200a of the first group of semiconductor chips 200 may be attached on the package substrate 110 by a first lower adhesive film 220a. That is, the first lower adhesive film 220a may be disposed the first lower semiconductor chip 200a and the package substrate 110. A second lower semiconductor chip 200b of the first group of semiconductor chips 200 may be attached on the first lower semiconductor chip 200a by a second lower adhesive film 220b. That is, the second lower adhesive film 220b may be disposed between the first lower semiconductor chip 200a and the second lower semiconductor chip 200b. The first lower adhesive film 220a and the second lower adhesive film 220b may include a die attach film (DAF). For example, a thickness of each of the first lower semiconductor chip 200a and the second lower semiconductor chip 200b may be within a range of about 40 micrometers (μm) to 110 μm. A thickness of each of the first lower adhesive film 220a and the second lower adhesive film 220b may be within a range of about 10 μm to 60 μm.

The first lower semiconductor chip 200a may be disposed such that a second surface (inactive surface) 202 opposite to a first surface (active surface) 201 faces the package substrate 110. The first surface 201 may be an upper surface of the first lower semiconductor chip 200a. A plurality of first chip pads 210a may be disposed on the first surface 201. The first lower semiconductor chip 200a may be stacked on the package substrate 110 such that the first surface 201 on which the first chip pads 210a are formed may face upward. That is, the first chip pads 210a may face upward from the first surface 201.

The second lower semiconductor chip 200b may be disposed such that has a second surface (inactive surface) 202 opposite to the first surface (active surface) 201 faces the first lower semiconductor chip 200a. A plurality of second chip pads 210b may be disposed on the first surface 201 of the second lower semiconductor chip 200b. The second lower semiconductor chip 200b may be stacked on the first lower semiconductor chip 200a such that the first surface 201 on which the second chip pads 210b are formed may face upward. That is, the second chip pads 210b may face upward.

The second lower semiconductor chip 200b may be stacked in a cascade structure on the first lower semiconductor chip 200a. The second lower semiconductor chip 200b may be offset in a first horizontal direction (X direction) on the first lower semiconductor chip 200a. The second lower semiconductor chip 200b may be offset in the first direction (X direction) such that the first chip pads 210a of the first lower semiconductor chip 200a may be exposed from the second lower semiconductor chip 200b. That is, the second lower semiconductor chip 200b may not overlap the first chip pads 210a of the first lower semiconductor chip 200a.

Herein, in a case that a chip is described as being offset from another chip, the chips may be partially offset from each other and include an overlapping portion.

The first lower semiconductor chip 200a may have a rectangular shape with four sides when viewed from plan view. In particular, the first lower semiconductor chip 200a may include a first side surface E1a and a second side surface E2a extending in a direction parallel to the second direction (Y direction) and facing each other. The first side surface E1a of the first lower semiconductor chip 200a may be arranged adjacent to the first side portion S1 of the package substrate 110, and the second side surface E2a of the first lower semiconductor chip 200a may be arranged adjacent to the second side portion S2 of the package substrate 110. The first chip pads 210a of the first lower semiconductor chip 200a may be arranged in the second direction (Y direction) along the first side surface E1a.

The second lower semiconductor chip 200b may have a rectangular shape with four sides when viewed from plan view. The second lower semiconductor chip 200b may have a same shape as the first lower semiconductor chip 200a. The second lower semiconductor chip 200b may have a size in a plan view that is the same as the first lower semiconductor chip 200a. The second lower semiconductor chip 200b may include a first side surface E1b and a second side surface E2b extending in a direction parallel to the second direction (Y direction) and facing each other. The first side surface E1b of the second lower semiconductor chip 200b may be arranged adjacent to the first side surface E1a of the first lower semiconductor chip 200a, and the second side surface E2b of the second lower semiconductor chip 200b may be arranged adjacent to the second side surface E2a of the first lower semiconductor chip 200a. The second chip pads 210b of the second lower semiconductor chip 200b may be arranged in the second direction (Y direction) along the first side surface E1b.

Accordingly, the first lower semiconductor chip 200a may have a first overhang region OH1 that protrudes from the first side surface E1b of the second lower semiconductor chip 200b, that is, a protruding portion. The first side surface E1a of the first lower semiconductor chip 200a and the first side surface E1b of the second lower semiconductor chip 200b may be spaced apart from each other by a first distance. The first distance may be equal to a length of the first overhang region OH1 in the first direction (X direction). For example, the first distance may be within a range of about 200 μm to 300 μm. A diameter of each of the first chip pads 210a and the second chip pads 210b may be in a range of about 30 μm to 60 μm.

In example embodiments, the second lower semiconductor chip 200b may have a same length in the first direction (X direction) as the first lower semiconductor chip 200a. Accordingly, the second lower semiconductor chip 200b may protrude from the second side surface E2a of the first lower semiconductor chip 200a. The protruding portion of the second lower semiconductor chip 200b may have a length in the first direction (X direction) equal to a length of the first overhang region OH1.

Referring to FIG. 1, the first upper semiconductor chip 300a may be adjacent to the second lower semiconductor chip 200b in a vertical direction perpendicular to the first direction (X direction) and the second direction (Y direction). The first upper semiconductor chip 300a may be completely overlap the second lower semiconductor chip 200b. That is, there may be no protrusion between the first upper semiconductor chip 300a and the second lower semiconductor chip 200b. In this case, the first upper semiconductor chip 300a and the second lower semiconductor chip 200b may be middle ones of the first group of semiconductor chips 200 and the second group of semiconductor chips 300.

In example embodiments, the first group of semiconductor chips 200 may be electrically connected to the package substrate 110 by first bonding wires 240. The first bonding wires may server as the conductive connection members. The first chip pads 210a and the second chip pads 210b of the first lower semiconductor chip 200a and the second lower semiconductor chip 200b may be connected to the first substrate pads 122a on the upper surface 112 of the package substrate 110 by the first bonding wires 240. The first bonding wires 240 may include a first lower wire 240a and a second lower wire 240b. The first lower wires 240a may electrically connect the first chip pads 210a of the first lower semiconductor chip 200a to the first substrate pad 122a. The second lower wires 240b may electrically connect the second chip pads 210b of the second lower semiconductor chip 200b to the first chip pads 210a of the first lower semiconductor chip 200a.

An electrical signal from the first lower semiconductor chip 200a may be transmitted to the package substrate 110 through the first lower wire 240a, and an electrical signal from the second lower semiconductor chip 200b may be transmitted to the package substrate 110 through the second lower wire 240b and the first lower wire 240a. Accordingly, when electrical signals are transmitted between the first lower semiconductor chip 200a and the package substrate 110 through the first lower wire 240a, noise, which may be caused by a bonding wire connected to the second lower semiconductor chip 200b may be reduced or eliminated.

In example embodiments, the second group of semiconductor chips 300 may be stacked on the first group of semiconductor chips 200. The second group of semiconductor chips 300 may be fixed using upper adhesive films 320. A first upper semiconductor chip 300a of the second group of semiconductor chips 300 may be attached on the second lower semiconductor chip 200b by a first upper adhesive film 320a. A second upper semiconductor chip 300b of the second group of semiconductor chips 300 may be attached on the first upper semiconductor chip 300a by a second upper adhesive film 320b. The first upper adhesive film 320a and the second upper adhesive film 320b may include a die attach film (DAF). For example, a thickness of each of the first upper semiconductor chip 300a and the second upper semiconductor chip 300b may be within a range of about 40 μm to 110 μm. A thickness of each of the first upper adhesive film 320a and the second upper adhesive film 320b may be within a range of about 10 μm to 60 μm.

The first upper semiconductor chip 300a may be disposed such that a second surface (inactive surface) 302 opposite to a first surface (active surface) 301 on which first upper chip pads 310a may be formed facing the second lower semiconductor chip 200b. The first upper semiconductor chip 300a may be stacked on the second lower semiconductor chip 200b such that the first surface 301 on which the first upper chip pads 310a are formed may face upward. The first upper semiconductor chip 300a may be stacked to overlap the second lower semiconductor chip 200b. The first upper semiconductor chip 300a may cover the second chip pads 210b of the second lower semiconductor chip 200b.

The first upper semiconductor chip 300a may have a rectangular shape with four sides when viewed from plan view. The first upper semiconductor chip 300a may have a shape the same as the first group of semiconductor chips 200. The first upper semiconductor chip 300a may have a size in a plan view that is the same as the first group of semiconductor chips 200. The first upper semiconductor chip 300a may include a first side surface Fla and a second side surface F2a extending in a direction parallel to the second direction (Y direction) and facing each other. The first side surface Fla of the first upper semiconductor chip 300a may be arranged on the same plane as the first side surface E1b of the second lower semiconductor chip 200b, and the second side surface F2a of the first upper semiconductor chip 300a may be arranged on the same plane as the second side surface E2b of the second lower semiconductor chip 200b. The first upper chip pads 310a of the first upper semiconductor chip 300a may be arranged in the second direction (Y direction) along the second side surface F2a.

The second upper semiconductor chip 300b may be disposed such that a second surface (inactive surface) 302 opposite to the first surface (active surface) 301 on which second upper chip pads 310b are formed faces the first upper semiconductor chip 300a. The second upper semiconductor chip 300b may be stacked on the first upper semiconductor chip 300a such that the first surface 301 on which the second upper chip pads 310b are formed may face upward.

The second upper semiconductor chip 300b may be stacked in a cascade structure on the first upper semiconductor chip 300a. The second upper semiconductor chip 300b may be offset on the first upper semiconductor chip 300a in a direction opposite to the first horizontal direction. The second upper semiconductor chip 300b may be offset in a direction opposite (−X direction) to the first direction (X direction) such that the first upper chip pads 310a of the first upper semiconductor chip 300a may be exposed from the second upper semiconductor chip 300b. That is, the second upper semiconductor chip 300b may not overlap the first upper chip pads 310a of the first upper semiconductor chip 300a. The second upper semiconductor chip 300b may be stacked to overlap the first lower semiconductor chip 200a. The second upper semiconductor chip 300b may be disposed to overlap the first overhang region OH1 of the first lower semiconductor chip 200a that protrudes from the first side surface E1b of the second lower semiconductor chip 200b.

The second upper semiconductor chip 300b may have a rectangular shape with four sides when viewed from plan view. The second upper semiconductor chip 300b may have a shape the same as the first upper semiconductor chip 300a. The second upper semiconductor chip 300b may have a size that is the same as the first upper semiconductor chip 300a. The second upper semiconductor chip 300b may include a first side surface F1b and a second side surface F2b extending in a direction parallel to the second direction (Y direction) and facing each other. The first side surface F1b of the second upper semiconductor chip 300b may be arranged adjacent to the first side surface Fla of the first upper semiconductor chip 300a, and the second side surface F2b of the second upper semiconductor chip 300b may be arranged adjacent to the second side surface F2a of the first upper semiconductor chip 300a. The second upper chip pads 310b of the second upper semiconductor chip 300b may be arranged in the second direction (Y direction) along the second side surface F2b. The first side surface F1b of the second upper semiconductor chip 300b may be arranged on the same plane as the first side surface E1a of the first lower semiconductor chip 200a, and the second side surface F2b of the second upper semiconductor chip 300b may be arranged on the same plane as the second side surface E2a of the first lower semiconductor chip 200a.

Accordingly, the second upper semiconductor chip 300b may have a second overhang region OH2 that protrudes from the first side surface F1b of the first upper semiconductor chip 300a, that is, a protruding region. The first side surface F2a of the second upper semiconductor chip 300b and the first side surface Fla of the first upper semiconductor chip 300a may be spaced apart from each other by a second distance. The second distance may be equal to a length of the second overhang region OH2 in the first direction (X direction). The second distance may be equal to the first distance, that is, the length of the first overhang region OH1 in the first direction (X direction). For example, the second distance may be in a range of about 200 μm to 300 μm.

In example embodiments, the second upper semiconductor chip 300b may have a same length in the first direction (X direction) as the first upper semiconductor chip 300a. Accordingly, the first upper semiconductor chip 300a may protrude from under the second side surface F2b of the second upper semiconductor chip 300b. The protruding portion of the first upper semiconductor chip 300a may have a length in the first direction (X direction) equal to a length of the second overhang region OH2 of the second upper semiconductor chip 300b.

In example embodiments, the second group of semiconductor chips 300 may be electrically connected to the package substrate 110 by second bonding wires 340 serving as the conductive connection members. The first upper chip pads 310a and the second upper chip pads 310b of the first upper semiconductor chip 300a and the second upper semiconductor chip 300b may be connected the second substrate pads 122b on the upper surface 112 of the package substrate 110 by the second bonding wires 340. The second bonding wires 340 may include a first upper wire 340a and a second upper wire 340b. The first upper wire 340a may electrically connect the first upper chip pad 310a of the first upper semiconductor chip 300a to the second substrate pad 122b. The second upper wires 340b may electrically connect the second upper chip pads 310b of the second upper semiconductor chip 300b to the first upper chip pads 310a of the first upper semiconductor chip 300a.

An electrical signal from the first upper semiconductor chip 300a may be transmitted to the package substrate 110 through the first upper wire 340a, and an electrical signal from the second upper semiconductor chip 300b may be transmitted to the package substrate 110 through the second upper wire 340b and the first upper wire 340a. Accordingly, when electrical signals are transmitted between the first upper semiconductor chip 300a and the package substrate 110 through the first upper wire 340a, noise, which may be caused by a bonding wire connected to the second upper semiconductor chip 300b may be reduced or eliminated.

It will be understood that the number, size, and arrangement of the first and second upper semiconductor chips are provided as examples, and the present inventive concept is not limited thereto. Additionally, although only a few chip pads are illustrated in the figures, it will be understood that the structure, shape, and arrangement of the chip pads are provided as examples, and the present inventive concept is not limited thereto.

In example embodiments, the first group of semiconductor chips 200 may be arranged to correspond one-to-one with the second group of semiconductor chips 300. The first lower semiconductor chip 200a and the second lower semiconductor chip 200b of the first group of semiconductor chips 200 may overlap the corresponding second upper semiconductor chip 300b and first upper semiconductor chip 300a of the second group of semiconductor chips 300, respectively.

The first side surface E1a of the lowermost lower semiconductor chip among the first group of semiconductor chips 200, that is, the first lower semiconductor chip 200a, and the first side surface F1b of the uppermost upper semiconductor chip among the second group of semiconductor chips 300, that is, the second upper semiconductor chip 300b may be located on the same plane as each other. The second side surface E2b of the uppermost lower semiconductor chip among the first group of semiconductor chips 200, that is, the second lower semiconductor chip 200b and the second side surface F2b of the lowermost upper semiconductor chip among the second group of semiconductor chips 300, that is, the first upper semiconductor chip 300a may be located on the same plane as each other.

In example embodiments, a molding member 400 may cover the first group of semiconductor chips 200 and the second group of semiconductor chips 300, the first bonding wires 240 and the second bonding wires 340, and the upper surface 112 of the package substrate 110. The molding member may include a thermosetting resin, for example, an epoxy mold compound (EMC).

A volume occupied by a molding region MR above the first overhang region OH1 of the first lower semiconductor chip 200a may be reduced by a volume of the second overhang region OH2 of the second upper semiconductor chip 300b that is disposed to overlap the first lower semiconductor chip 200a. Accordingly, it may be possible to reduce or prevent an interfacial peeling failure due to a difference in hygro-swelling expansion displacements at an edge portion of the first overhang region OH1 of the first lower semiconductor chip 200a below the molding region MR. For example, it may be possible to reduce or prevent an interfacial peeling failure between the first lower semiconductor chip 200a and the molding region MR at an upper surface of the first overhang region OH1.

In example embodiments, external connection pads 132 for providing electrical signals may be formed on the lower surface 114 of the package substrate 110. The external connection pads 132 may be exposed by a second insulating layer 130. The second insulating layer 130 may include a silicon oxide layer, a silicon nitride layer, or a silicon oxynitride layer. External connection members 500 may be disposed on the external connection pads 132 of the package substrate 110 for electrical connection with external devices. For example, the external connection member 500 may be a solder ball. The semiconductor package 100 may be mounted on a module substrate (not illustrated) using the solder balls to form a semiconductor module.

As mentioned above, the semiconductor package 100 may include the first group of semiconductor chips 200 disposed on the package substrate 110, the second group of semiconductor chips 300 stacked on the first group of semiconductor chips 200, and the molding member 400 covering the first group of semiconductor chips 200 and the second group of semiconductor chips 300 on the package substrate 110.

The first lower semiconductor chip 200a and the second lower semiconductor chip 200b of the first group of semiconductor chips 200 may be sequentially offset in the first horizontal direction (X direction), and the first upper semiconductor chip 300a and the second upper semiconductor chip 300b of the second group of semiconductor chips 300 may be sequentially offset in a direction opposite (−X direction) to the first horizontal direction (X direction). The first lower semiconductor chip 200a may overlap the second upper semiconductor chip 300b, and the second lower semiconductor chip 200b may overlap the first upper semiconductor chip 300a.

The volume occupied by the molding region MR above the first overhang region OH1 of the first lower semiconductor chip 200a may be reduced by the volume of the second overhang region OH2 of the second upper semiconductor chip 300b that is disposed to overlap the first lower semiconductor chip 200a. Accordingly, it may be possible to reduce or prevent an interfacial peeling defect due to a difference in hygro-swelling expansion displacements at the edge portion of the first overhang region OH1 of the first lower semiconductor chip 200a below the molding region MR. Further, occurrence of defects in an unbiased High Acceleration Stress Test (uHAST) may be reduced or minimized.

In addition, the first chip pads 210a and the second chip pads 210b of the first lower semiconductor chip 200a and the second lower semiconductor chip 200b stacked in the cascade manner may be electrically connected to the package substrate 110 by the first lower wires 240a and the second lower wires 240b using a chip-to-chip wire bonding method. The first upper chip pads 310a and the second upper chip pads 310b of the first upper semiconductor chip 300a and the second upper semiconductor chip 300b stacked in a cascade manner be electrically connected to the package substrate 110 by the first upper wires 340a and the second upper wires 340b using a chip-to-chip wire bonding method. Accordingly, it may be possible to reduce impedance mismatch between chips and provide improved electrical characteristics suitable for a high-speed memory package.

Hereinafter, a method of manufacturing the semiconductor package of FIG. 1 will be described.

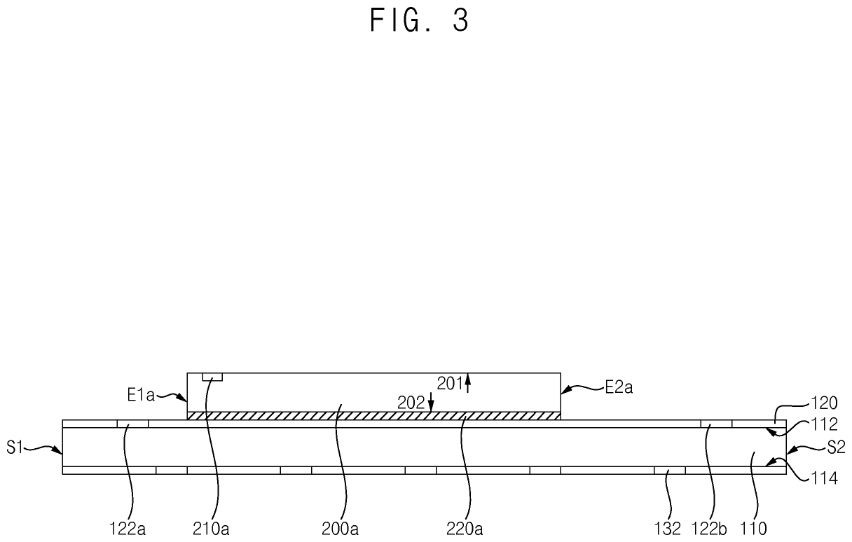

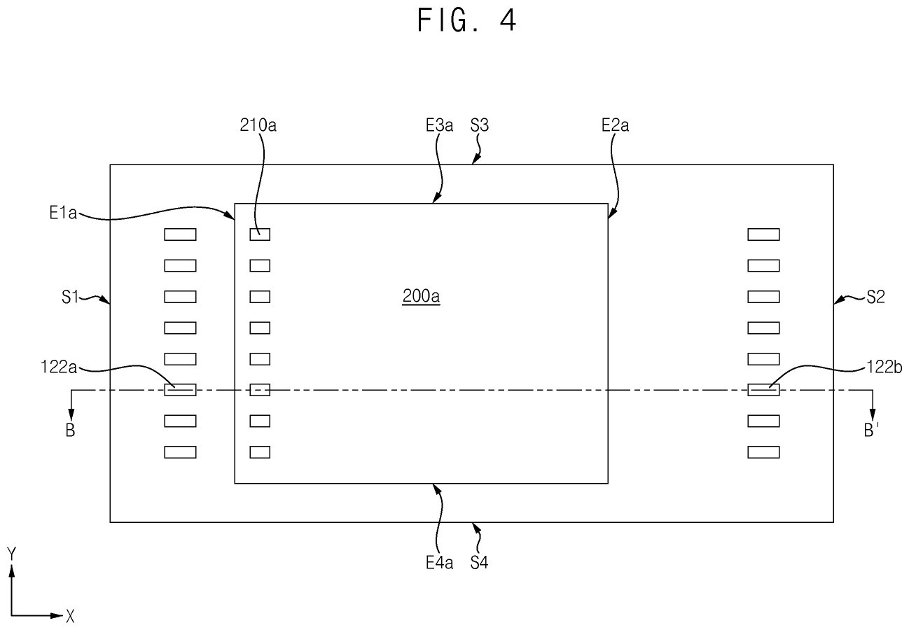

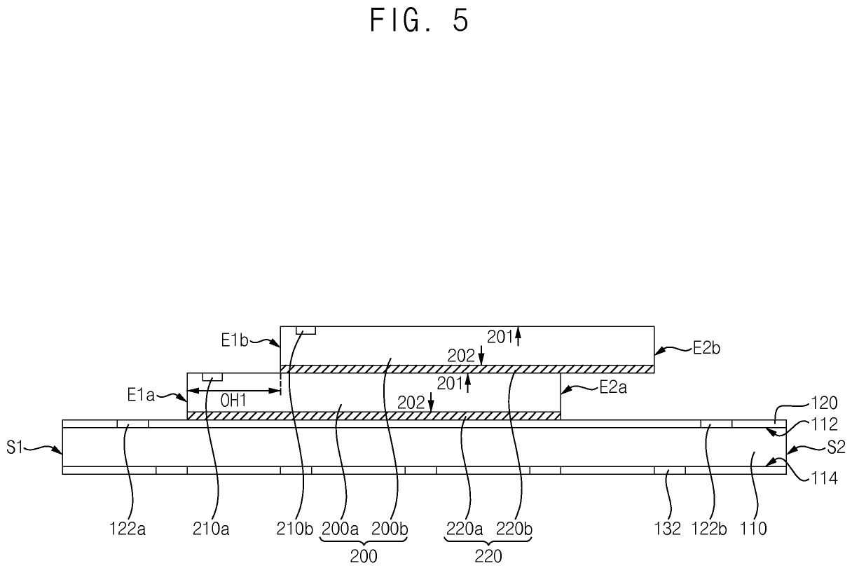

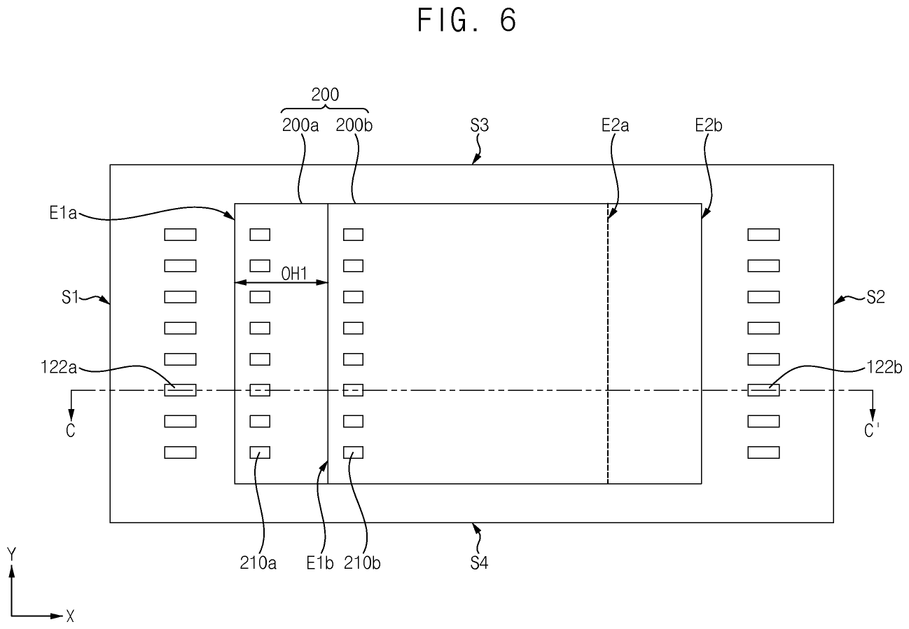

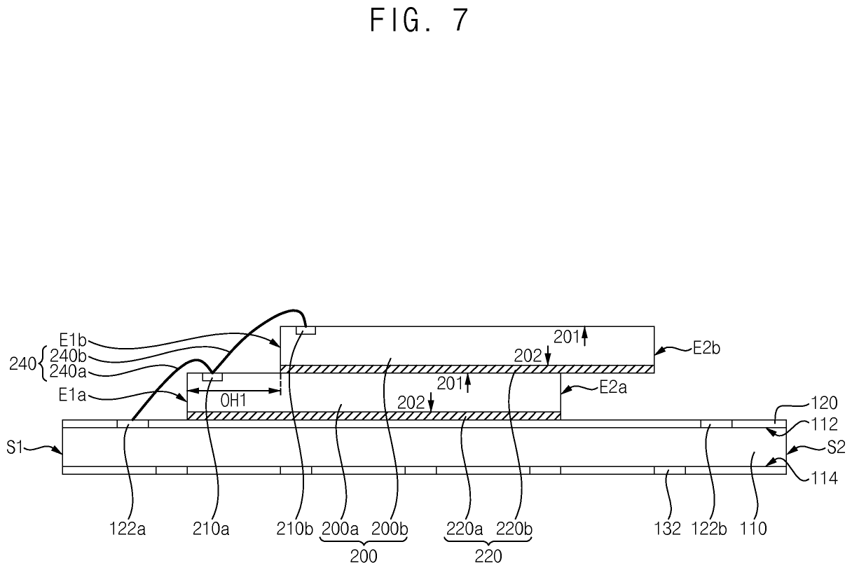

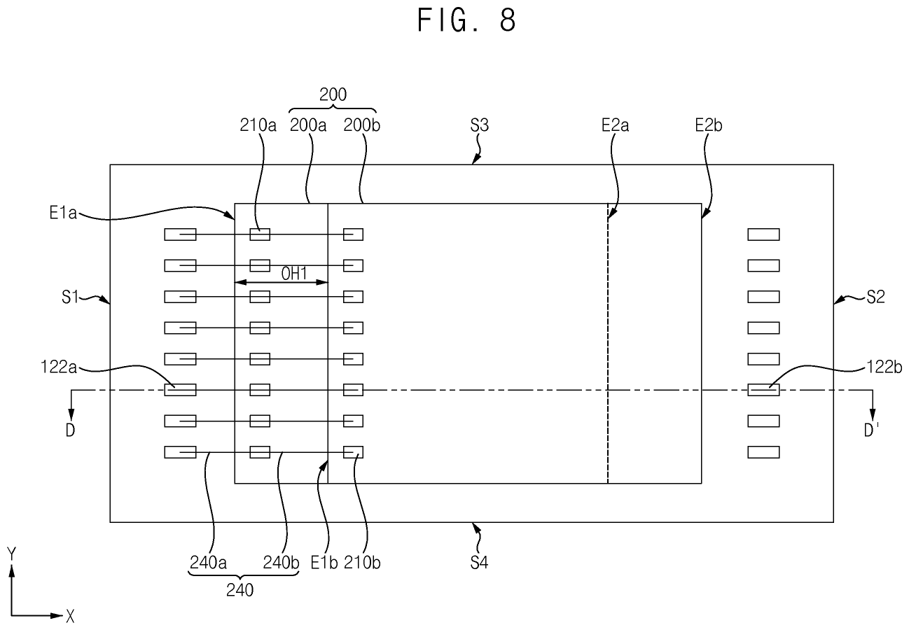

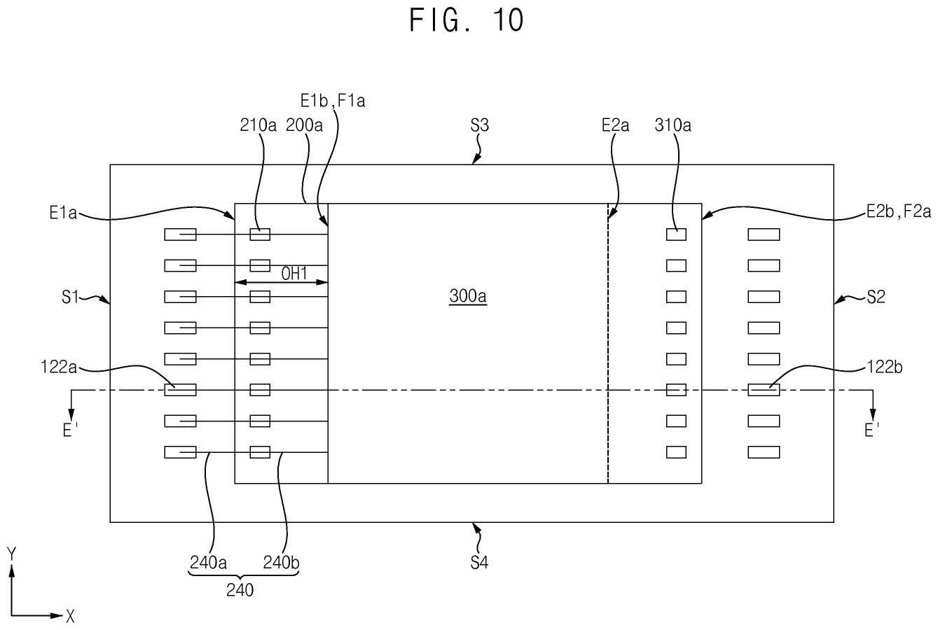

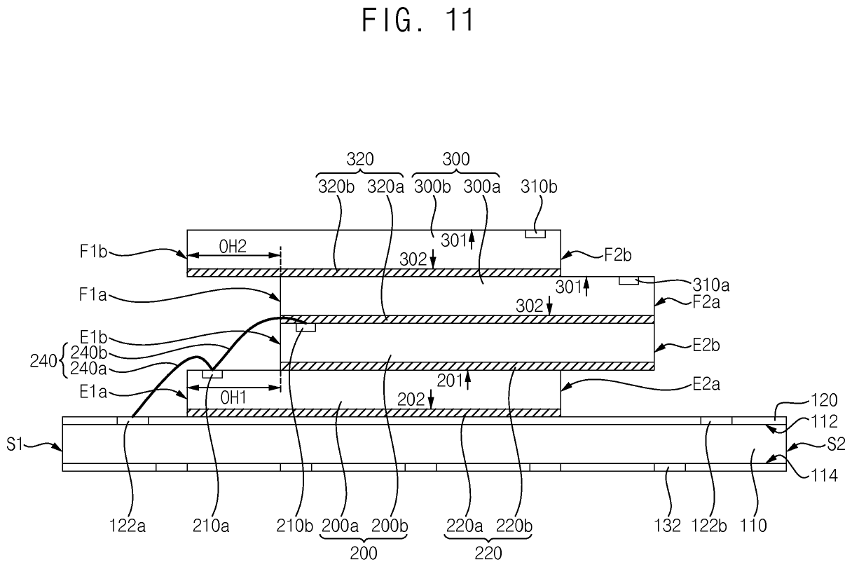

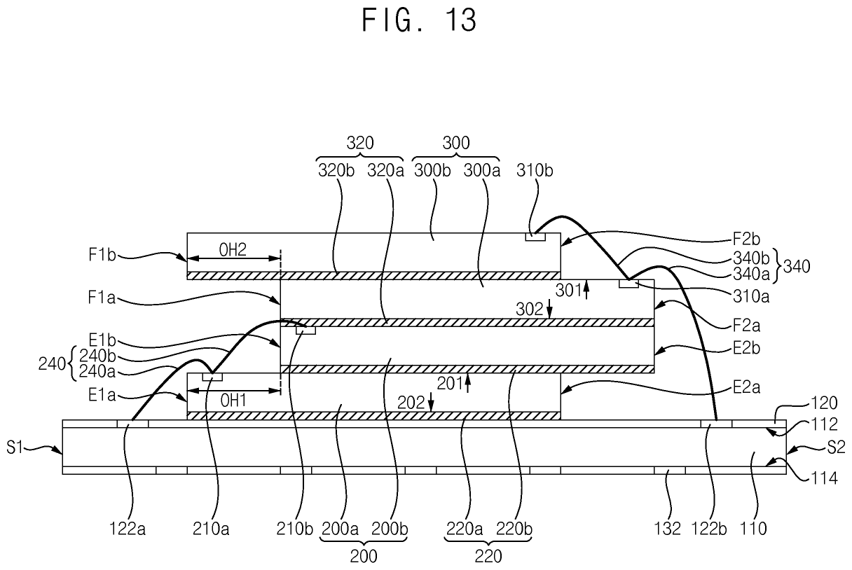

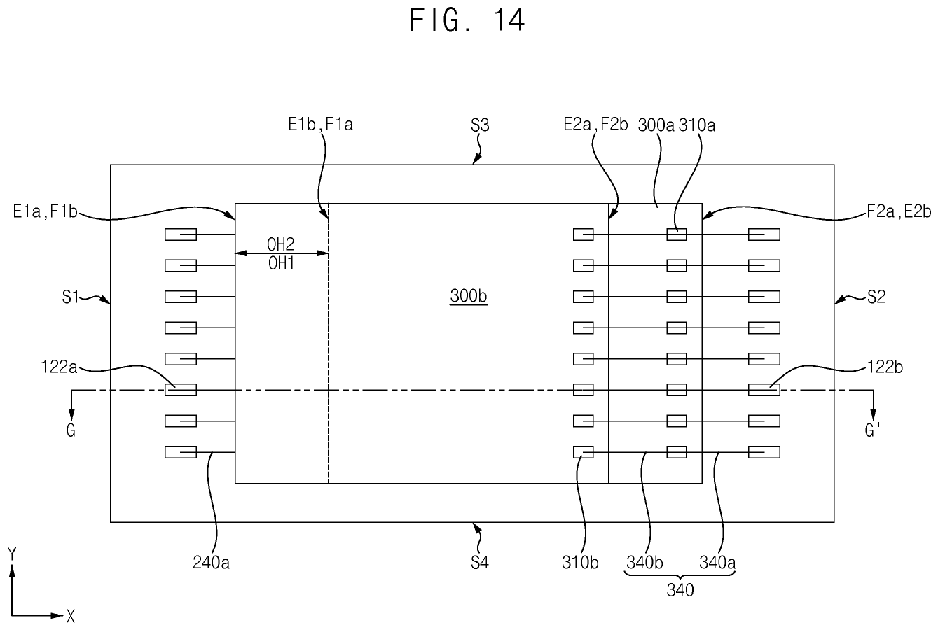

FIGS. 3 to 15 are views illustrating a method of manufacturing a semiconductor package in accordance with example embodiments. FIG. 3 is a cross-sectional view taken along the line B-B′ in FIG. 4. FIG. 5 is a cross-sectional view taken along the line C-C′ in FIG. 6. FIG. 7 is a cross-sectional view taken along the line D-D′ in FIG. 8. FIG. 10 is a cross-sectional view taken along the line E-E′ in FIG. 11. FIG. 13 is a cross-sectional view taken along the line G-G′ in FIG. 14.

Referring to FIG. 3 and FIG. 4, a first lower semiconductor chip 200a may be mounted on a package substrate 110. An individual semiconductor chip cut from a wafer W through a dicing process may be provided as the first lower semiconductor chip.

In example embodiments, the package substrate 110 may be a substrate having an upper surface 112 and a lower surface 114 facing each other. For example, the package substrate 110 may include a printed circuit board (PCB). The package substrate 110 may be a multilayer circuit board having vias and various circuits therein. The package substrate 110 may include internal wirings that may serve as channels for electrical connections with a plurality of semiconductor chips including the first lower semiconductor chip to be mounted thereon.

The package substrate 110 may include a first side portion S1 and a second side portion S2 extending in a direction perpendicular to the upper surface 112 and parallel to a second direction (Y direction) and facing each other, and a third side portion S3 and a fourth side portion S4 extending in a direction parallel to a first direction (X direction) perpendicular to the second direction (Y direction) and facing each other.

The package substrate 110 may include first substrate pads 122a and second substrate pads 122b arranged along sides of the package substrate 110. The substrate pads may be respectively connected to the wirings. The wirings may extend on the upper surface 112 or inside the package substrate 110. For example, at least a portion of the wiring may be used as a landing pad or as the substrate pad on the substrate.

Although only some substrate pads are illustrated in the figures, it will be understood that the number, shape, and arrangement of the substrate pads are provided as examples, and the present inventive concept is not limited thereto. Since the wirings as well as the substrate pads are well known in the art to which the present inventive concept pertains, illustration and description concerning the above elements may be omitted.

A first insulating layer 120 may be formed on the upper surface 112 of the package substrate 110 to expose the first substrate pads 122a and the second substrate pads 122b. The first insulating layer 120 may cover the upper surface 112 of the package substrate 110 and may expose the first substrate pads 122a and the second substrate pads 122b. For example, the first insulating layer 120 may include a solder resist.

In example embodiments, the first lower semiconductor chip 200a may be attached on the package substrate 110 using a first lower adhesive film 220a. The first lower semiconductor chip 200a may be attached to the package substrate 110 using the first lower adhesive film 220a such as a die attach film (DAF) by a die attach process. For example, a thickness of the first lower semiconductor chip 200a may be within a range of about 40 μm to 110 μm. A thickness of the first lower adhesive film 220a may be within a range of about 10 μm to 60 μm.

The first lower semiconductor chip 200a may be disposed such that a second surface (inactive surface) 202 opposite to a first surface (active surface) 201 on which first chip pads 210a are formed may face the package substrate 110. The first lower semiconductor chip 200a may be stacked on the package substrate 110 such that the first surface 201 on which the first chip pads 210a are formed may face upward.

The first lower semiconductor chip 200a may have a rectangular shape with four sides when viewed from plan view. In particular, the first lower semiconductor chip 200a may include a first side surface E1a and a second side surface E2a extends in a direction parallel to the second direction (Y direction) and facing each other, and a third side surface E3a and a fourth side surface E4a extending in a direction parallel to the first direction (X direction) perpendicular to the second direction and facing each other. The first side surface E1a of the first lower semiconductor chip 200a may be arranged adjacent to the first side portion S1 of the package substrate 110, and the second side surface E2a of the first lower semiconductor chip 200a may be arranged adjacent to the second side portion S2 of the package substrate 110. The first chip pads 210a of the first lower semiconductor chip 200a may be arranged in the second direction (Y direction) along the first side surface E1a.

The first lower semiconductor chip may be a logic chip including a logic circuit. The logic chip may be a controller that controls memory chips. The first lower semiconductor chip may be a processor chip such as ASIC, an application processor (AP), etc. serving as a host such as a CPU, GPU, or SOC.

Alternatively, the first lower semiconductor chip may include a memory chip including a memory circuit. For example, the first lower semiconductor chip may include volatile memory devices such as SRAM devices, DRAM devices, and non-volatile memory devices such as flash memory devices, PRAM devices, MRAM devices, RRAM devices.

Referring to FIG. 5 and FIG. 6, a second lower semiconductor chip 200b may be stacked on the first lower semiconductor chip 200a. Similar to the first lower semiconductor chip 200a, an individual semiconductor chip cut from the wafer W through a dicing process may be provided as the second lower semiconductor chip. The second lower semiconductor chip may include a memory chip of the same type as the first lower semiconductor chip. Accordingly, a first group of semiconductor chips 200 including the first lower semiconductor chip 200a and the second lower semiconductor chip 200b may be stacked on the package substrate 110.

In example embodiments, the second lower semiconductor chip 200b may be attached on the first lower semiconductor chip 200a using a second lower adhesive film 220b such as a die attach film DAF by a die attach process. For example, a thickness of the second lower adhesive film 220b may be within a range of about 10 μm to 40 μm.

The second lower semiconductor chip 200b may be disposed such that a second surface (inactive surface) opposite to a first surface (active surface) on which second chip pads 210b are formed faces the first lower semiconductor chip 200a. The second lower semiconductor chip 200b may be stacked on the first lower semiconductor chip 200a such that the first surface 201 on which the second chip pads 210b are formed may face upward.

The second lower semiconductor chip 200b may be stacked in a cascade structure on the first lower semiconductor chip 200a. The second lower semiconductor chip 200b may be offset in a first horizontal direction on the first lower semiconductor chip 200a. The second lower semiconductor chip 200b may be offset in the first direction (X direction) such that the first chip pads 210a of the first lower semiconductor chip 200a may be exposed from the second lower semiconductor chip 200b.

The second lower semiconductor chip 200b may have a rectangular shape with four sides when viewed from plan view. The second lower semiconductor chip 200b may have the same shape as the first lower semiconductor chip 200a. The second lower semiconductor chip 200b may include a first side surface E1b and a second side surface E2b extending in a direction parallel to the second direction (Y direction) and facing each other. The first side surface E1b of the second lower semiconductor chip 200b may be arranged adjacent to the first side surface E1a of the first lower semiconductor chip 200a, and the second side surface E2b of the second lower semiconductor chip 200b may be arranged adjacent to the second side surface E2a of the first lower semiconductor chip 200a. The second chip pads 210b of the second lower semiconductor chip 200b may be arranged in the second direction (Y direction) along the first side surface E1b.

Accordingly, the first lower semiconductor chip 200a may have a first overhang region OH1 that protrudes from the first side surface E1b of the second lower semiconductor chip 200b, that is, a protruding portion. The first side surface E1a of the first lower semiconductor chip 200a and the first side surface E1b of the second lower semiconductor chip 200b may be spaced apart from each other by a first distance. The first distance may be equal to a length of the first overhang region OH1 in the first direction (X direction). For example, the first distance may be within a range of about 200 μm to 300 μm. A diameter of each of the first chip pads 210a and the second chip pads 210b may be in a range of about 30 μm to 60 μm.

It will be understood that the number, size, and arrangement of the first and second lower semiconductor chips are provided as examples, and the present inventive concept is not limited thereto. Additionally, although only a few chip pads are illustrated in the figures, it will be understood that the structure, shape, and arrangement of the chip pads are provided as examples, and the present inventive concept is not limited thereto.

Referring to FIG. 7 and FIG. 8, the first group of semiconductor chips 200 may be electrically connected to the package substrate 110 by first bonding wires 240 serving as conductive connection members.

In example embodiments, a wire bonding process may be performed to connect the first chip pads 210a and the second chip pads 210b of the first lower semiconductor chip 200a and the second lower semiconductor chip 200b to first substrate pads 122a on the upper surface 112 of the package substrate 110 using the first bonding wires 240. The first bonding wires 240 may include a first lower wire 240a and a second lower wire 240b. The first lower wire 240a may electrically connect the first chip pad 210a of the first lower semiconductor chip 200a to the first substrate pad 122a. The second lower wire 240b may electrically connect the second chip pad 210b of the second lower semiconductor chip 200b to the first chip pad 210a of the first lower semiconductor chip 200a.

An electrical signal from the first lower semiconductor chip 200a may be transmitted to the package substrate 110 through the first lower wire 240a, and an electrical signal from the second lower semiconductor chip 200b may be transmitted to the package substrate 110 through the second lower wire 240b and the first lower wire 240a. Accordingly, when electrical signals are transmitted between the first lower semiconductor chip 200a and the package substrate 110 through the first lower wire 240a, noise, which may be caused by a bonding wire connected to the second lower semiconductor chip 200b may be reduced.

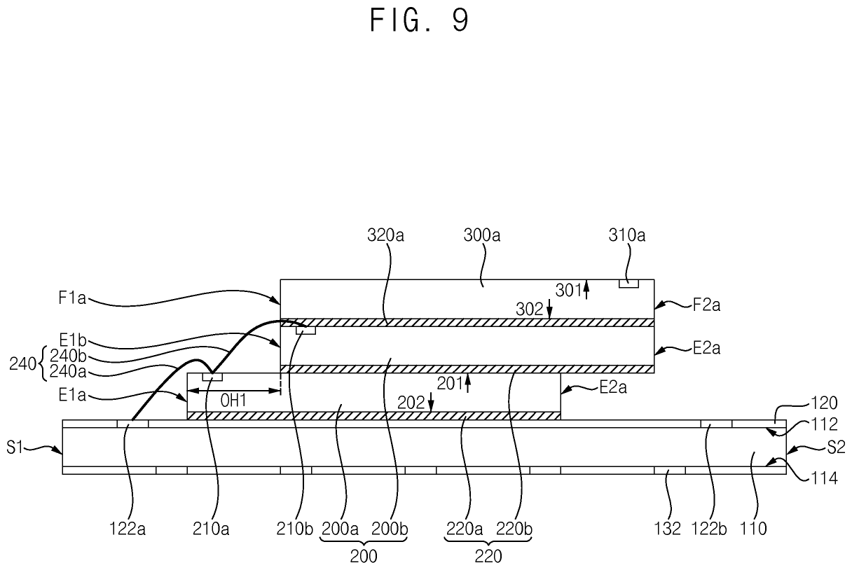

Referring to FIG. 9 and FIG. 10, a first upper semiconductor chip 300a may be stacked on the second lower semiconductor chip 200b. Similar to the first group of semiconductor chips 200, an individual semiconductor chip cut from the wafer W through a dicing process may be provided as the first upper semiconductor chip. The first upper semiconductor chip may include a memory chip of the same type as the first group of semiconductor chips.

In exemplary embodiments, the first upper semiconductor chip 300a may be attached on the second lower semiconductor chip 200b using a first upper adhesive film 320a such as a die attach film DAF by a die attach process. For example, a thickness of the first upper adhesive film 320a may be within a range of about 10 μm to 40 μm.

The first upper semiconductor chip 300a may be disposed such that a second surface (inactive surface) 302 opposite to a first surface (active surface) 301 on which the first upper chip pads 310a may be formed facing the second lower semiconductor chip 200b. The first upper semiconductor chip 300a may be stacked on the second lower semiconductor chip 200b such that the first surface 301 on which the first upper chip pads 310a are formed may face upward. The first upper semiconductor chip 300a may be stacked to overlap the second lower semiconductor chip 200b. The first upper semiconductor chip 300a may cover the second chip pads 210b of the second lower semiconductor chip 200b.

The first upper semiconductor chip 300a may have a rectangular shape with four sides when viewed from plan view. The first upper semiconductor chip 300a may have a shape the same as the first group of semiconductor chips 200. The first upper semiconductor chip 300a may have a size in a plan view that is the same as the first group of semiconductor chips 200. The first upper semiconductor chip 300a may include a first side surface Fla and a second side surface F2a extending in a direction parallel to the second direction (Y direction) and facing each other. The first side surface Fla of the first upper semiconductor chip 300a may be arranged on the same plane as the first side surface E1b of the second lower semiconductor chip 200b, and the second side surface F2a of the first upper semiconductor chip 300a may be arranged on the same plane as the second side surface E2b of the second lower semiconductor chip 200b. The first upper chip pads 310a of the first upper semiconductor chip 300a may be arranged in the second direction (Y direction) along the second side surface F2a.

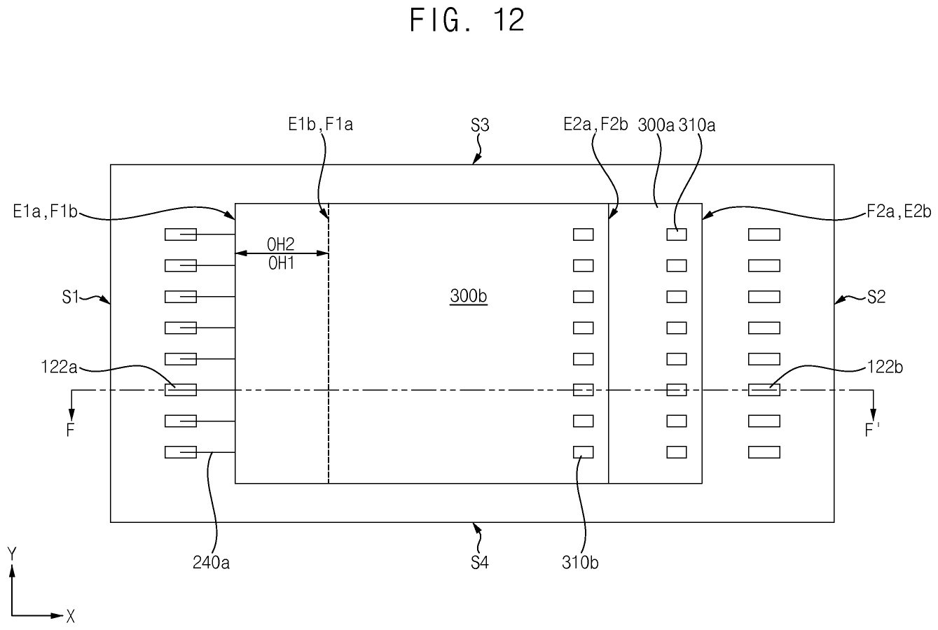

Referring to FIG. 11 and FIG. 12, a second upper semiconductor chip 300b may be stacked on the first upper semiconductor chip 300a. Similar to the first upper semiconductor chip 300a, an individual semiconductor chip cut from the wafer W through a dicing process may be provided as the second upper semiconductor chip. The second upper semiconductor chip may include a memory chip of the same type as the first upper semiconductor chip. Accordingly, a second group of semiconductor chips 300 including the first upper semiconductor chip 300a and the second upper semiconductor chip 300b may be stacked on the first group of semiconductor chips 200.

In exemplary embodiments, the second upper semiconductor chip 300b be attached on the first upper semiconductor chip 300a using a second upper adhesive film 320b such as a die attach film DAF by a die attach process. For example, a thickness of the second upper adhesive film 320b may be within a range of about 10 μm to 40 μm.

The second upper semiconductor chip 300b may be disposed such that a second surface (inactive surface) 302 opposite to the first surface (active surface) 301 on which the second upper chip pads 310b are formed may face the first upper semiconductor chip 300a. The second upper semiconductor chip 300b may be stacked on the first upper semiconductor chip 300a such that the first surface 301 on which the second upper chip pads 310b are formed may face upward.

The second upper semiconductor chip 300b may be stacked in a cascade structure on the first upper semiconductor chip 300a. The second upper semiconductor chip 300b may be offset on the first upper semiconductor chip 300a in a direction opposite to the first horizontal direction. The second upper semiconductor chip 300b may be offset in the direction opposite (−X direction) to the first direction (X direction) such that the first upper chip pads 310a of the first upper semiconductor chip 300a are exposed from the second upper semiconductor chip 300b. The second upper semiconductor chip 300b may be stacked to overlap the first lower semiconductor chip 200a. The second upper semiconductor chip 300b may be disposed to overlap the first overhang region OH1 of the first lower semiconductor chip 200a that protrudes from the first side surface E1b of the second lower semiconductor chip 200b.

The second upper semiconductor chip 300b may have a rectangular shape with four sides when viewed from plan view. The second upper semiconductor chip 300b may have a shape the same as the first upper semiconductor chip 300a. The second upper semiconductor chip 300b may have a size in a plan view that is the same as the first upper semiconductor chip 300a. The second upper semiconductor chip 300b may include a first side surface F1b and a second side surface F2b extending in a direction parallel to the second direction (Y direction) and facing each other. The first side surface F1b of the second upper semiconductor chip 300b may be arranged adjacent to the first side surface Fla of the first upper semiconductor chip 300a, and the second side surface F2b of the second upper semiconductor chip 300b may be arranged adjacent to the second side surface F2a of the first upper semiconductor chip 300a. The second upper chip pads 310b of the second upper semiconductor chip 300b may be arranged in the second direction (Y direction) along the second side surface F2b. The first side surface F1b of the second upper semiconductor chip 300b may be arranged on the same plane as the first side surface E1a of the first lower semiconductor chip 200a, and the second side surface F2b of the second upper semiconductor chip 300b may be arranged on the same plane as the second side surface E2a of the first lower semiconductor chip 200a.

Accordingly, the second upper semiconductor chip 300b may have a second overhang region OH2 that protrudes from the first side surface F1b of the first upper semiconductor chip 300a, that is, a protruding region. The first side surface F2a of the second upper semiconductor chip 300b and the first side surface Fla of the first upper semiconductor chip 300a may be spaced apart from each other by a second distance. The second distance may be equal to a length of the second overhang region OH2 in the first direction (X direction). The second distance may be equal to the first distance, that is, the length of the first overhang region OH1 in the first direction (X direction). For example, the second distance may be in a range of about 200 μm to 300 μm.

It will be understood that the number, size, and arrangement of the first and second upper semiconductor chips are provided as examples, and the present inventive concept is not limited thereto. Additionally, although only a few chip pads are illustrated in the figures, it will be understood that the structure, shape, and arrangement of the chip pads are provided as examples, and the present inventive concept is not limited thereto.

Referring to FIG. 13 and FIG. 14, the second group of semiconductor chips 300 may be electrically connected to the package substrate 110 by second bonding wires 340 serving as conductive connection members.

In example embodiments, a wire bonding process may be performed to connect the first upper chip pads 310a and the second upper chip pads 310b of the first upper semiconductor chip 300a and the second upper semiconductor chip 300b to second substrate pads 122b on the upper surface 112 of the package substrate 110. The second bonding wires 340 may include a first upper wire 340a and a second upper wire 340b. The first upper wire 340a may electrically connect the first upper chip pad 310a of the first upper semiconductor chip 300a to the second substrate pad 122b. The second upper wires 340b may electrically connect the second upper chip pads 310b of the second upper semiconductor chip 300b to the first upper chip pads 310a of the first upper semiconductor chip 300a.

An electrical signal from the first upper semiconductor chip 300a may be transmitted to the package substrate 110 through the first upper wire 340a, and an electrical signal from the second upper semiconductor chip 300b may be transmitted to the package substrate 110 through the second upper wire 340b and the first upper wire 340a. Accordingly, when electrical signals are transmitted between the first upper semiconductor chip 300a and the package substrate 110 through the first upper wire 340a, noise, which may be caused by a bonding wire connected to the second upper semiconductor chip 300b, may be reduced or eliminated.

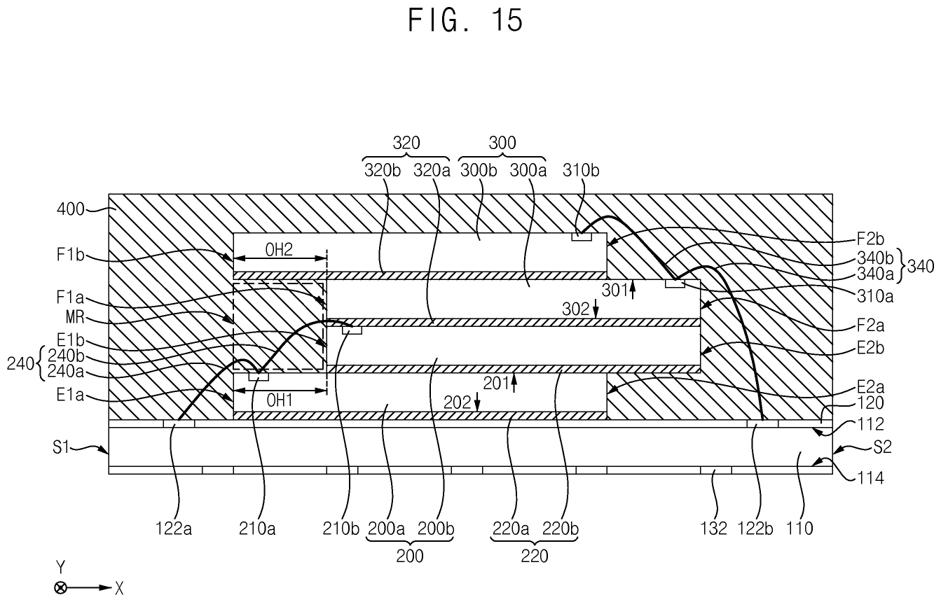

Referring to FIG. 15, a molding member may be formed on the upper surface 112 of the package substrate 110 to cover the first group of semiconductor chips 200, the second group of semiconductor chips 300, the first bonding wires 240, and the second bonding wires 340. The molding member may include a thermosetting resin, for example, an epoxy mold compound (EMC).

A volume occupied by a molding region MR above the first overhang region OH1 of the first lower semiconductor chip 200a may be reduced by a volume of the second overhang region OH2 of the second upper semiconductor chip 300b that is disposed to overlap the first lower semiconductor chip 200a. Accordingly, it may be possible to reduce or prevent an interfacial peeling failure due to a difference in hygro-swelling expansion displacements at an edge portion of the first overhang region OH1 of the first lower semiconductor chip 200a below the molding region MR.

External connection members 500 may be formed on external connection pads 132 on the lower surface 114 of the package substrate 110 and may complete a semiconductor package 100 of FIG. 1.

For example, the external connection members 500 may include solder balls. The external connection members 500 may be respectively formed on the external connection pads 132 on the lower surface 114 of the package substrate 110 through a solder ball attach process.

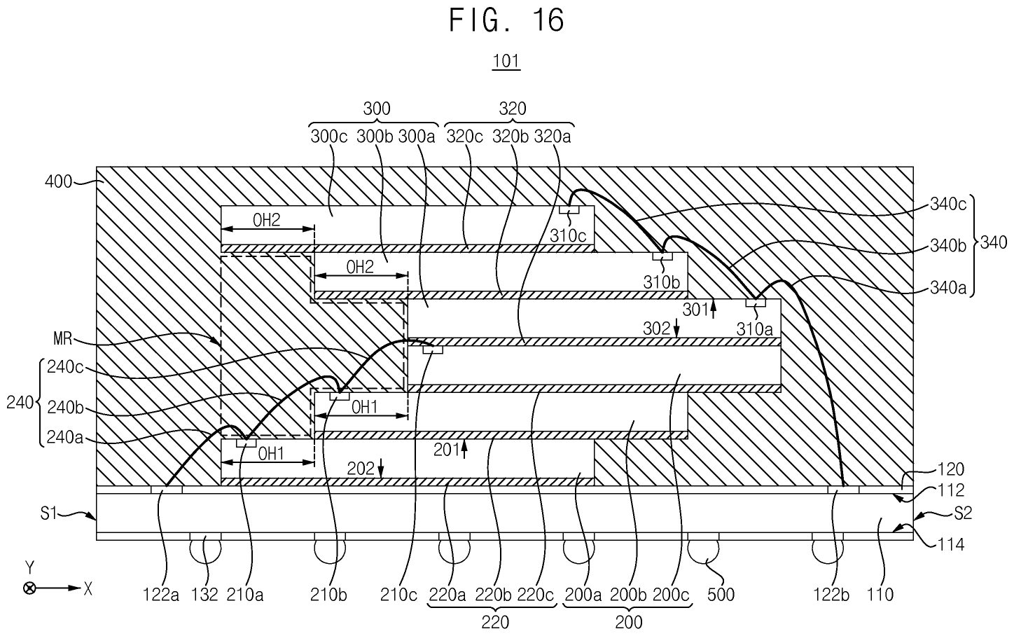

FIG. 16 is a cross-sectional view illustrating a semiconductor package in accordance with example embodiments. The semiconductor package may be substantially the same as the semiconductor package described with reference to FIG. 1 and FIG. 2 except for arrangements and the numbers of a first group of semiconductor chips and a second group of semiconductor chips. The same reference numerals may be used to refer to the same or like elements and any further repetitive explanation concerning the above elements may be omitted.

Referring to Referring to FIG. 16, a semiconductor package 101 may include a first group of semiconductor chips 200 including the first lower semiconductor chip 200a, the second lower semiconductor chip 200b, and the third lower semiconductor chip 200c sequentially stacked on one another, and a second group of semiconductor chips 300 stacked on the first group of semiconductor chips 200 and including the first upper semiconductor chip 300a, the second upper semiconductor chip 300b, and the third upper semiconductor chip 300c sequentially stacked on one another.

In example embodiments, the first lower semiconductor chip 200a, second lower semiconductor chip 200b, and third lower semiconductor chip 200c of the first group of semiconductor chips 200 may be sequentially stacked on a package substrate 110. That is, the first lower semiconductor chip 200a may be disposed on the package substrate 110, the second lower semiconductor chip 200b may be disposed on the first lower semiconductor chip 200a, and the third lower semiconductor chip 200c may be disposed on the second lower semiconductor chip 200b. The second lower semiconductor chip 200b may be attached on the third lower semiconductor chip 200c by a third lower adhesive film 220c. Each of the first lower semiconductor chip 200a, the second lower semiconductor chip 200b, and the third lower semiconductor chip200c may be stacked such that first surfaces 201 of the first group of semiconductor chips 200 on which the first chip pads 210a, the second chip pads 210b and the third chip pads 210c are formed may face upward. That is, each of the first lower semiconductor chip 200a, the second lower semiconductor chip 200b, and the third lower semiconductor chip 200c may have a first surface that may be an upper surface of the respective chip. The first lower semiconductor chip 200a, the second lower semiconductor chip 200b and the third lower semiconductor chip 200c may be sequentially offset in a first horizontal direction (X direction).

The first upper semiconductor chip 300a, the second upper semiconductor chip 300b, and the third upper semiconductor chip 300c of the second group of semiconductor chips 300 may be sequentially stacked on the first group of semiconductor chips 200. The second upper semiconductor chip 300b may be attached on the third upper semiconductor chip 300c by a third upper adhesive film 320c. Each of the first upper semiconductor chip 300a, the second upper semiconductor chip 300b, and the third upper semiconductor chip 300c may be stacked such that first surfaces 301 of the second group of semiconductor chips 300 on which first upper chip pads 310a, the second upper chip pads 310b and third upper chip pads 310c are formed may face upward. That is, each of the first upper semiconductor chip 300a, the second upper semiconductor chip 300b, and the third upper semiconductor chip 300c may have a first surface that may be an upper surface of the respective chip. The first upper semiconductor chip 300a, the second upper semiconductor chip 300b, and the third upper semiconductor chip 300c may be sequentially offset in a direction opposite (−X direction) to the first horizontal direction (X direction).

In example embodiments, the first group of semiconductor chips 200 may be arranged to correspond one-to-one with the second group of semiconductor chips 300. The first lower semiconductor chip 200a, the second lower semiconductor chip 200b, and the third lower semiconductor chip 200c of the first group of semiconductor chips 200 may overlap with the corresponding the third upper semiconductor chip 300c, the second upper semiconductor chip 300b, and the first upper semiconductor chip 300a of the second group of semiconductor chips 300, respectively.

The first bonding wires 240 may further include a third lower wire 240c. The third lower wire 240c may electrically connect a third chip pad 210c of the third lower semiconductor chip 200c to the second chip pad 210b of the second lower semiconductor chip 200b. The second bonding wires 340 may further include a third upper wire 340c. The third upper wires 340c may electrically connect a third upper chip pads 310c of the third upper semiconductor chip 300c to the second upper chip pads 310b of the second upper semiconductor chip 300b.

The first group of semiconductor chips 200 may be arranged in one-to-one correspondence with the second group of semiconductor chips 300. For example, the first lower semiconductor chip 200a may overlap the third upper semiconductor chip 300c, the second lower semiconductor chip 200b may overlap the second upper semiconductor chip 300b, and the third lower semiconductor chip 200c may overlap the first upper semiconductor chip 300a. In this case, the first upper semiconductor chip 300a may completely overlap the third lower semiconductor chip 200c. That is, there may be no protrusion between the third lower semiconductor chip 200c and the first upper semiconductor chip 300a. Further, the third chip pads 210c at an upper surface of the third lower semiconductor chip 200c may be covered by the first upper adhesive film 320a. Portions of a third lower wires 240c connected to the third chip pads 210c may be encapsulated by the first upper adhesive film 320a.

A first side surface of the lowermost lower semiconductor chip among the first group of semiconductor chips 200, that is, the first lower semiconductor chip 200a and a first side surface of the uppermost upper semiconductor chip among the second group of semiconductor chips 300, that is, the third upper semiconductor chip may be located on the same plane as each other. A second side surface of the uppermost lower semiconductor chip among the first group of semiconductor chips 200, that is, the third lower semiconductor chip 200c and a second side surface of the lowermost upper semiconductor chip among the second group of semiconductor chips 300, that is, the first upper semiconductor chip 300a may be located on the same plane as each other.

Referring to FIG. 16, the first upper semiconductor chip 300a may be adjacent to the third lower semiconductor chip 200c in a vertical direction perpendicular to the first direction (X direction) and the second direction (Y direction). The first upper semiconductor chip 300a may be completely overlap the third lower semiconductor chip 200c. That is, there may be no protrusion between the first upper semiconductor chip 300a and the third lower semiconductor chip 200c. In this case, the first upper semiconductor chip 300a and the third lower semiconductor chip 200c may be middle ones of the first group of semiconductor chips 200 and the second group of semiconductor chips 300.

A volume occupied by a molding region MR above a first overhang region OH1 of the first lower semiconductor chip 200a and a first overhang region OH1 of the second lower semiconductor chip 200b may be reduced by a volume of a second overhang region OH2 of the third upper semiconductor chip 300c that is disposed to overlap the first lower semiconductor chip 200a and a second overhang region OH2 of the second upper semiconductor chip 300b that is disposed to overlap the second lower semiconductor chip 200b. Accordingly, it may be possible to reduce or prevent interfacial peeling defects due to differences in hygro-swelling expansion displacements at edge portions of the first overhang region OH1 of the first lower semiconductor chip 200a and the first overhang region OH1 of the second lower semiconductor chip 200b below the molding region MR. For example, it may be possible to reduce or prevent an interfacial peeling failure between the first lower semiconductor chip 200a and the molding region MR at an upper surface of the first overhang region OH1 and between the second lower semiconductor chip 200b and the molding region MR at an upper surface of the second lower semiconductor chip 200b.

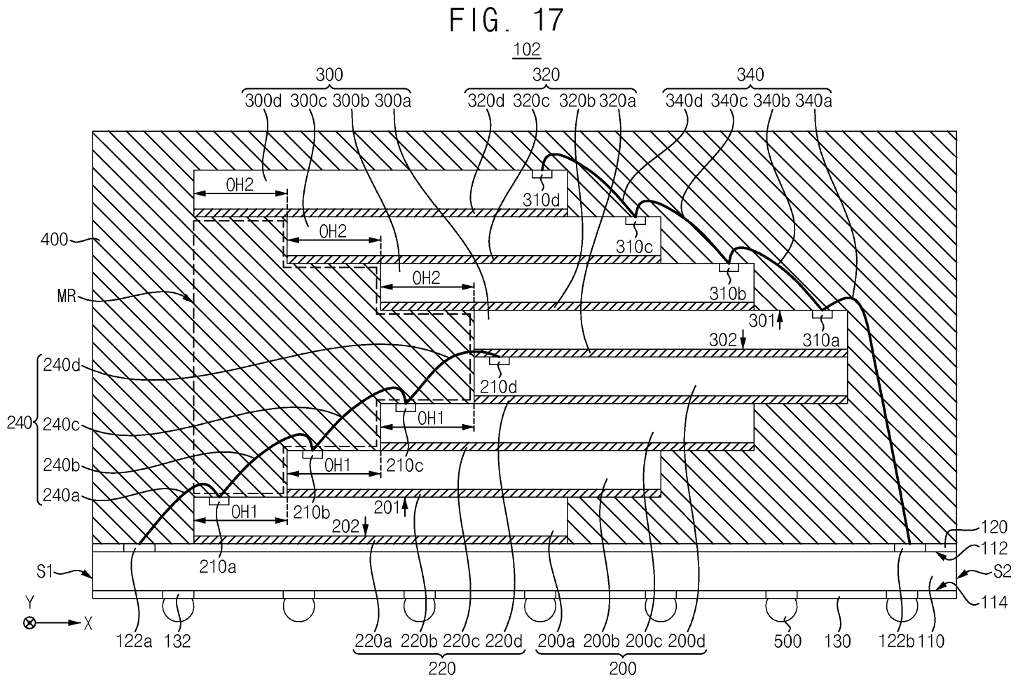

FIG. 17 is a cross-sectional view illustrating a semiconductor package in accordance with example embodiments. The semiconductor package is substantially the same as the semiconductor package described with reference to FIG. 1 and FIG. 2 except for arrangements and the numbers of a first group of semiconductor chips and a second group of semiconductor chips. Thus, same reference numerals may be used to refer to the same or like elements and any further repetitive explanation concerning the above elements may be omitted.

Referring to FIG. 17, a semiconductor package 102 may include a first group of semiconductor chips 200 including first lower semiconductor chip 200a, second lower semiconductor chip 200b, third lower semiconductor chip 200c, and fourth lower semiconductor chip 200d sequentially stacked on one another, and a second group of semiconductor chips 300 stacked on the first group of semiconductor chips 200 and including first upper semiconductor chip 300a, second upper semiconductor chip 300b, third upper semiconductor chip 300c, and fourth upper semiconductor chip 300d sequentially stacked on one another.

In example embodiments, the first lower semiconductor chip 200a, second lower semiconductor chip 200b, third lower semiconductor chip 200c, and fourth lower semiconductor chip 200d of the first group of semiconductor chips 200 may be sequentially stacked on a package substrate 110. The third lower semiconductor chip 200c may be attached on the fourth lower semiconductor chip 200d by a fourth lower adhesive film 220d. The first lower semiconductor chip 200a, the second lower semiconductor chip 200b, the third lower semiconductor chip 200c, and the fourth lower semiconductor chip 200d may be stacked such that first surfaces 201 of the first group of semiconductor chips 200 on which the first chip pads 210a, the second chip pads 210b, the third chip pads 210c and fourth chip pads 210d are formed may face upward. The first lower semiconductor chip 200a, the second lower semiconductor chip 200b, the third lower semiconductor chip 200c, and the fourth lower semiconductor chip 200d may be sequentially offset in a first horizontal direction (X direction).

The first upper semiconductor chip 300a, the second upper semiconductor chip 300b, the third upper semiconductor chip 300c, and the fourth upper semiconductor chip 300d of the second group of semiconductor chips 300 may be sequentially stacked on the first group of semiconductor chips 200. The third upper semiconductor chip 300c may be attached on the fourth upper semiconductor chip 300d by a fourth upper adhesive film 320d. The first upper semiconductor chip 300a, the second upper semiconductor chip 300b, the third upper semiconductor chip 300c, and the fourth upper semiconductor chip 300d may be stacked such that a first surface 301 on which the first upper chip pads 310a, the second upper chip pads 310b, the third upper chip pads 310c and the fourth upper chip pads 310d are formed may face upward. The first upper semiconductor chip 300a, the second upper semiconductor chip 300b, the third upper semiconductor chip 300c, and the fourth upper semiconductor chip 300d may be sequentially offset in a direction opposite (−X direction) to the first horizontal direction (X direction).

The first bonding wires 240 may further include a fourth lower wire 240d. The fourth lower wire 240d may electrically connect a fourth chip pad 210d of the fourth lower semiconductor chip 200d to the third chip pad 210c of the third lower semiconductor chip 200c. The second bonding wires 340 may further include a fourth upper wire 340d. The fourth upper wires 340d may electrically connect a fourth upper chip pads 310d of the fourth upper semiconductor chip 300d to the third upper chip pads 310c of the third upper semiconductor chip 300c.

The first group of semiconductor chips 200 may be arranged in one-to-one correspondence with the second group of semiconductor chips 300. For example, the first lower semiconductor chip 200a may overlap the fourth upper semiconductor chip 300d, the second lower semiconductor chip 200b may overlap the third upper semiconductor chip 300c, and the third lower semiconductor chip 200c may overlap the second upper semiconductor chip 300b, and the fourth lower semiconductor chip 200d may overlap the first upper semiconductor chip 300a. In this case, the first upper semiconductor chip 300a may completely overlap the fourth lower semiconductor chip 200d. That is, there may be no protrusion between the first upper semiconductor chip 300a and the fourth lower semiconductor chip 200d. Further, the fourth chip pads 210d at an upper surface of the fourth lower semiconductor chip 200d may be covered by the first upper adhesive film 320a. Portions of a fourth lower wires 240d connected to the fourth chip pads 210d may be encapsulated by the first upper adhesive film 320a.

Referring to FIG. 17, the first upper semiconductor chip 300a may be adjacent to the fourth lower semiconductor chip 200d in a vertical direction perpendicular to the first direction (X direction) and the second direction (Y direction). The first upper semiconductor chip 300a may be completely overlap the fourth lower semiconductor chip 200d. That is, there may be no protrusion between the first upper semiconductor chip 300a and the fourth lower semiconductor chip 200d. In this case, the first upper semiconductor chip 300a and the fourth lower semiconductor chip 200d may be middle ones of the first group of semiconductor chips 200 and the second group of semiconductor chips 300.

A volume occupied by a molding region MR above on a first overhang region OH1 of the first lower semiconductor chip 200a, a first overhang region OH1 of the second lower semiconductor chip 200b and a first overhang region OH1 of the third lower semiconductor chip 200c may be reduced by a volume of a second overhang region OH2 of the fourth upper semiconductor chip 300d that is disposed to overlap the first lower semiconductor chip 200a, a second overhang region OH2 of the third upper semiconductor chip 300c that is disposed to overlap the second lower semiconductor chip 200b and a second overhang region OH2 of the second upper semiconductor chip 300b that is disposed to overlap the third lower semiconductor chip 200c. Accordingly, it may be possible to reduce or prevent interfacial peeling defects due to differences in hygro-swelling expansion displacements at edge portions of the first overhang region OH1 of the first lower semiconductor chip 200a, the first overhang region OH1 of the second lower semiconductor chip 200b, and the first overhang region OH1 of the third lower semiconductor chip 200c below the molding region MR. For example, it may be possible to reduce or prevent an interfacial peeling failure between the first lower semiconductor chip 200a and the molding region MR at an upper surface of the first overhang region OH1, between the second lower semiconductor chip 200b and the molding region MR at an upper surface of the second lower semiconductor chip 200b, and between the third lower semiconductor chip 200c and the molding region MR at an upper surface of the third lower semiconductor chip 200c.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate having an upper surface and a lower surface opposite to each other, the package substrate including a first side portion and a second side portion extending in a direction parallel to a first direction and facing each other;
a first group of semiconductor chips disposed on the upper surface of the package substrate, the first group of semiconductor chips including a first lower semiconductor chip and a second lower semiconductor chip stacked on the first lower semiconductor chip and respectively comprise first surfaces facing upwards on which chip pads are formed, and the first group of semiconductor chips are sequentially offset in a second direction perpendicular to the first direction;
a second group of semiconductor chips disposed on the first group of semiconductor chips, the second group of semiconductor chips including a first upper semiconductor chip and a second upper semiconductor chip stacked on the first upper semiconductor chip and respectively comprise a first surfaces facing upwards on which upper chip pads are formed, and the second group of semiconductor chips are sequentially offset in the direction opposite to the second direction;
a plurality of first bonding wires electrically connecting the chip pads to a plurality of first substrate pads of the package substrate;
a plurality of second bonding wires electrically connecting the upper chip pads to a plurality of second substrate pads of the package substrate; and
a molding member covering the first group of semiconductor chips and the second group of semiconductor chips on the upper surface of the package substrate,
wherein the second upper semiconductor chip overlaps an overhang region of the first lower semiconductor chip that protrudes from a side of the second lower semiconductor chip.

2. The semiconductor package of claim 1, wherein the first substrate pads are arranged along the first side portion of the package substrate, and the second substrate pads are arranged along the second side portion of the package substrate.

3. The semiconductor package of claim 1, wherein the first group of semiconductor chips and the second group of semiconductor chips are attached by adhesive films.

4. The semiconductor package of claim 3, wherein the adhesive films include a die attach film.

5. The semiconductor package of claim 3, wherein the adhesive film has a thickness of about 10 micrometers (μm) to 40 μm.

6. The semiconductor package of claim 1, wherein a first side surface of the first lower semiconductor chip and a first side surface of the second lower semiconductor chip that are adjacent to the first side portion of the package substrate are spaced apart from each other by a first distance, and
wherein a second side surface of the first upper semiconductor chip and a second side surface of the second upper semiconductor chip that are adjacent to the second side portion of the package substrate are spaced apart from each other by the first distance.

7. The semiconductor package of claim 6, wherein the first distance is within a range of about 200 micrometers (μm) to 300 μm.

8. The semiconductor package of claim 1, wherein a first side surface of the first lower semiconductor chip and a first side surface of the second upper semiconductor chip that are adjacent to the first side portion of the package substrate are located on a first plane, and
wherein a second side surface of the second lower semiconductor chip and a second side surface of the first upper semiconductor chip that are adjacent to the second side portion of the package substrate are located on a second plane.

9. The semiconductor package of claim 1, wherein the plurality of first bonding wires include a first lower wire that connects the chip pad of the first lower semiconductor chip to the first substrate pad and a second lower wire that electrically connects the chip pad of the second lower semiconductor chip to the chip pad of the first lower semiconductor chip, and
wherein the plurality of second bonding wires include a first upper wire that connects the chip pad of the first upper semiconductor chip to the second substrate pad and a second upper wire that connects the chip pad of the second upper semiconductor chip to the first upper semiconductor chip.

10. The semiconductor package of claim 1, further comprising:
external connection members disposed on external connection pads on the lower surface of the package substrate.

11. A semiconductor package, comprising:
a package substrate;
a first group of semiconductor chips disposed on the package substrate, the first group of semiconductor chips including at least two lower semiconductor chips that are stacked offset in a first horizontal direction such that a first surface of each of the at least two lower semiconductor chips on which chip pads are formed face upward;
a second group of semiconductor chips disposed on the first group of semiconductor chips, the second group of semiconductor chips including at least two upper semiconductor chips that are stacked offset in a direction opposite to the first horizontal direction such that a first side of each of the at least two upper semiconductor chips on which upper chip pads are formed face upward;
a plurality of first bonding wires electrically connecting the chip pads to a plurality of first substrate pads of the package substrate;
a plurality of second bonding wires electrically connecting the upper chip pads to a plurality of second substrate pads of the package substrate; and
a molding member covering the first group of semiconductor chips and the second group of semiconductor chips on the package substrate,
wherein each of the first group of semiconductor chips and the second group of semiconductor chips has a first side surface and a second side surface opposite to the first side surface, and
wherein the first side surfaces of the first group of semiconductor chips are arranged in one-to-one correspondence with the first side surfaces of the second group of semiconductor chips.

12. The semiconductor package of claim 11, wherein the first side surface of a lowermost lower semiconductor chip among the first group of semiconductor chips and the first side surface of an uppermost upper semiconductor chip among the second group of semiconductor chips are located on a first plane, and
wherein the first side surface of an uppermost lower semiconductor chip among the first group of semiconductor chips and the first side surface of a lowermost upper semiconductor chip among the second group of semiconductor chips are located on a second plane.

13. The semiconductor package of claim 11, wherein the first side surface of a lowermost lower semiconductor chip among the first group of semiconductor chips and the first side surface of a second lowermost lower semiconductor chip among the first group of semiconductor chips are spaced apart by a first distance, and
wherein the first side surface of an uppermost upper semiconductor chip among the second group of semiconductor chips and the first side surface of a second uppermost upper semiconductor chip among the second group of semiconductor chips are spaced apart by the first distance.

14. The semiconductor package of claim 13, wherein the first distance is within a range of about 200 micrometers (μm) to 300 μm.

15. The semiconductor package of claim 11, wherein the first group of semiconductor chips and the second group of semiconductor chips are attached by adhesive films.

16. The semiconductor package of claim 15, wherein the adhesive films include a die attach film.

17. The semiconductor package of claim 15, wherein the adhesive film has a thickness of about 10 micrometers (μm) to 40 μm.

18. The semiconductor package of claim 11, wherein the first substrate pads are arranged spaced apart along a first side portion of the package substrate adjacent to the first side surfaces of the first group of semiconductor chips and the second group of semiconductor chips, and the second substrate pads are arranged spaced apart along a second side portion of the package substrate opposite to the first side portion.

19. The semiconductor package of claim 11, wherein the plurality of first bonding wires include a lower wire that connects the chip pads of the at least two lower semiconductor chips to each other, and
wherein the plurality of second bonding wires include an upper wire that connects the upper chip pads of the at least two upper semiconductor chips to each other.

20. A semiconductor package, comprising:
a package substrate;
a first group of semiconductor chips disposed on the package substrate, the first group of semiconductor chips including at least two lower semiconductor chips that are stacked offset in a first horizontal direction such that a first surface of each of the at least two lower semiconductor chips on which chip pads are formed face upward;
a second group of semiconductor chips disposed on the first group of semiconductor chips, the second group of semiconductor chips including at least two upper semiconductor chips that are stacked offset in a direction opposite to the first horizontal direction such that a first surface of each of the at least two upper semiconductor chips on which upper chip pads are formed face upward;
a plurality of first bonding wires electrically connecting the chip pads to a plurality of first substrate pads of the package substrate;
a plurality of second bonding wires electrically connecting the upper chip pads to a plurality of second substrate pads of the package substrate; and
a molding member covering the first group of semiconductor chips and the second group of semiconductor chips on the package substrate,
wherein each of the first group of semiconductor chips and the second group of semiconductor chips has a first side surface adjacent to a first side portion of the package substrate and a second side surface opposite to the first side portion,
wherein the first group of semiconductor chips are arranged in one-to-one correspondence with the second group of semiconductor chips,
wherein each of the at least two lower semiconductor chips of the first group of semiconductor chips overlap with corresponding ones of the at least two upper semiconductor chips of the second group of semiconductor chips,
wherein the first side surface of a lowermost lower semiconductor chip among the first group of semiconductor chips and the first side surface of an uppermost upper semiconductor chip among the second group of semiconductor chips are located on a first plane, and
wherein the first side surfaces of middle ones of the first group of semiconductor chips and the second group of semiconductor chips disposed adjacent to each other are located on a second plane different than the first plane.
